(19) United States
(12) Patent Application Publication
(10) Pub. No.: US 2024/0072026 A1
(43) Pub. Date: Feb. 29, 2024

(54) SEMICONDUCTOR DEVICE, METHOD OF MANUFACTURING SAME, AND SEMICONDUCTOR PACKAGE

(71) Applicant: Mitsubishi Electric Corporation, Tokyo (JP)

(72) Inventors: Kazutake KADOWAKI, Chiyoda-ku, Tokyo (JP); Kozo HARADA, Chiyoda-ku, Tokyo (JP); Hodaka ROKUBUICHI, Chiyoda-ku, Tokyo (JP)

(73) Assignee: Mitsubishi Electric Corporation, Tokyo (JP)

(21) Appl. No.: 18/271,849

(22) PCT Filed: Jan. 15, 2021
(86) PCT No.: PCT/JP2021/001341

§ 371 Date: Jul. 12, 2023

(51) Int. Cl. H01L 25/16; H01L 23/00; H01L 23/29; H01L 23/31; H01L 23/498

(52) U.S. Cl. CPC H01L 25/165; H01L 23/293; H01L 23/3142; H01L 23/49811; H01L 24/32; H01L 24/48; H01L 24/73; H01L 2224/32245; H01L 2224/48249; H01L 2224/73265; H01L 2924/13091

(57) ABSTRACT

A semiconductor device according to the present disclosure includes: a semiconductor element; a plurality of conductive members each electrically connected to the semiconductor element and each extending upward; a sealing resin to seal the semiconductor element and the conductive member and to form a protrusion that covers a perimeter of a tip portion of each of the plurality of conductive members; a control substrate provided with a through hole into which the protrusion is inserted, the control substrate having a control electrode; and a flexible wiring to connect the control electrode and the tip portion of the conductive member to each other, the flexible wiring having flexibility. With such a configuration, a trouble due to external force or stress applied to the semiconductor device or the semiconductor package can be prevented and the semiconductor device or the semiconductor package having an excellent durability can be obtained.

### TECHNICAL FIELD

The present disclosure relates to a semiconductor device using a semiconductor package having a semiconductor element, a method of manufacturing the semiconductor device, and the semiconductor package.

### BACKGROUND ART

A semiconductor device used in a power conversion device of an on-vehicle device, an industrial device, or the like, or a semiconductor package constituting part of the semiconductor device is required to have a high durability because external force or stress due to heat, vibration, impact, or the like is generated therein and a high voltage is applied thereto. Conventionally, the following semiconductor device has been disclosed: a semiconductor package in which a semiconductor element and a portion of a conductive member are sealed with a sealing resin and a tip of the conductive member is exposed is attached to a control substrate opposed thereto, and the tip of the conductive member and an electrode of the control substrate are connected to each other by a solder to provide a high-strength bonding portion (for example, PTL 1). There is also disclosed a semiconductor device in which an insulation property is improved by covering, with an underfill material, a conductive member exposed between a semiconductor package and a control substrate (for example, PTL 2).

### CITATION LIST

### Patent Literature

PTL 1: Japanese Patent Laying-Open No. 2013-21371 (FIG. 2)
PTL 2: WO 2014/103133 (FIG. 1)

### SUMMARY OF INVENTION

### Technical Problem

However, in manufacturing, use, or the like of such a semiconductor device or semiconductor package, external force or stress may be generated in the solder serving as the bonding member used to connect the conductive member of the semiconductor package to the electrode of the control substrate, or may be generated in the underfill material used to cover the conductive member of the semiconductor package, with the result that a damage such as detachment or cracking may be caused in the bonding member or the insulation resin to result in a trouble in electrical connection, insulation, or the like of the semiconductor device. Therefore, it has been required to obtain a semiconductor device or semiconductor package which has an excellent durability with the trouble due to the external force or stress being prevented.

The present disclosure has been made to solve the above-described problem and has an object to provide a semiconductor device or semiconductor package having an excellent durability.

### Solution to Problem

A semiconductor device according to the present disclosure includes: a semiconductor element; a plurality of conductive members each electrically connected to the semiconductor element and each extending upward; a sealing resin to seal the semiconductor element and the conductive members and to form a protrusion that covers a perimeter of a tip portion of each of the plurality of conductive members; a control substrate provided with a through hole into which the protrusion is inserted, the control substrate having a control electrode; and a flexible wiring to connect the control electrode and the tip portion of the conductive member to each other, the flexible wiring having flexibility.

A method of manufacturing a semiconductor device according to the present disclosure includes: a semiconductor package fixing step of fixing a semiconductor package to a base plate, the semiconductor package having a sealing resin to form a protrusion that covers a perimeter of a tip portion of each of a plurality of conductive members; a protrusion inserting step of inserting the protrusion into a through hole provided in a control substrate; and a flexible wiring connecting step of connecting, by a flexible wiring through wire bonding, the tip portion and a control electrode provided on the control substrate.

Further, a semiconductor package according to the present disclosure includes: a semiconductor element; a plurality of conductive members each electrically connected to the semiconductor element and each extending upward; and a sealing resin to seal the semiconductor element and the conductive members and to form a protrusion that covers a perimeter of a tip portion of each of the plurality of conductive members.

### Advantageous Effects of Invention

According to the present disclosure, a semiconductor device or semiconductor package can be obtained which has an excellent durability with a trouble due to generated external force or stress in the semiconductor device or semiconductor package being prevented.

### BRIEF DESCRIPTION OF DRAWINGS

FIG. 1 is a schematic diagram showing a schematic configuration of a semiconductor device in a first embodiment.

FIG. 2 is a schematic diagram showing a schematic configuration of a semiconductor package in the first embodiment.

FIG. 3 is a schematic cross sectional view showing the schematic configuration of the semiconductor package in the first embodiment.

FIG. 4 is an explanatory diagram showing a correspondence relation between semiconductor packages and a control substrate in the first embodiment.

FIG. 5 is an explanatory diagram showing a method of manufacturing the semiconductor package in the first embodiment.

FIG. 6 is a schematic cross sectional view showing a connection state of a flexible wiring of the semiconductor device in the first embodiment.

FIG. 7 is a schematic cross sectional view showing a schematic configuration of a modification of the semiconductor device in the first embodiment.

FIG. 8 is a schematic diagram showing a schematic configuration of a modification of the semiconductor device in the first embodiment.

FIG. 9 is a schematic cross sectional view showing a relation between a protrusion of a semiconductor package and a control substrate in a second embodiment.

FIG. 10 is a schematic diagram showing a schematic configuration of a modification of the semiconductor package in each of the first and second embodiments.

FIG. 11 is a schematic cross sectional view showing the schematic configuration of the modification of the semiconductor package in each of the first and second embodiments.

FIG. 12 is a schematic diagram showing the schematic configuration of the modification of the semiconductor package in each of the first and second embodiments.

### DESCRIPTION OF EMBODIMENTS

As a result of diligent study, the present inventors have found the following matter: by employing such a sealing structure of a semiconductor package that a protrusion to cover a perimeter of a tip portion of each of a plurality of conductive members of the semiconductor package is formed so as not to expose the perimeter of the tip portion of each of the conductive members, an insulation property of each conductive member between the semiconductor package and the control substrate can be improved without using an underfill material, thereby preventing occurrence of a trouble such as detachment and cracking of the underfill material. Also, it has been found that by employing a configuration in which the conductive member of the semiconductor package and the control electrode of the control substrate are connected to each other by a flexible wiring having flexibility, a damage due to fatigue of a bonding portion at a connection point therebetween can be suppressed to improve stability of electrical connection. Further, it has been found that a semiconductor device or semiconductor package having an excellent durability can be obtained.

Hereinafter, a semiconductor device, a method of manufacturing the semiconductor device, a semiconductor package, and a method of manufacturing the semiconductor package according to embodiments of the present disclosure will be described in detail with reference to figures.

### First Embodiment

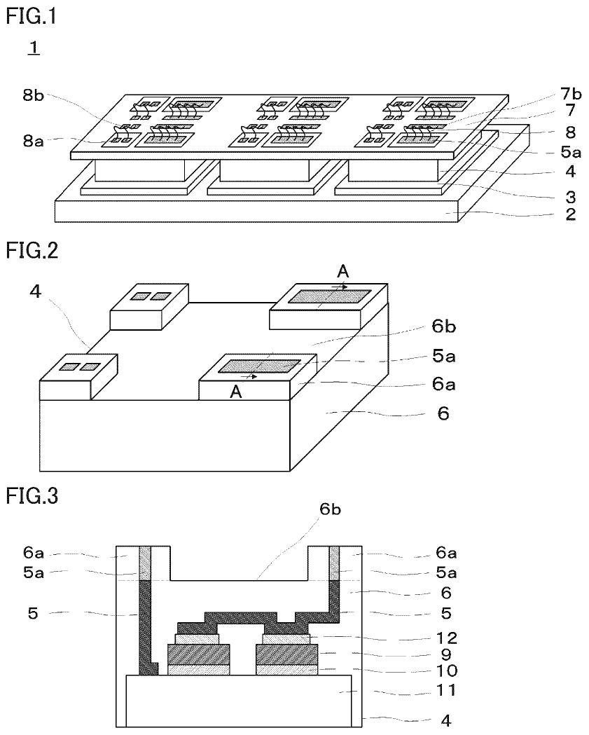

FIG. 1 is a schematic diagram showing a schematic configuration of a semiconductor device 1 of the present embodiment. Semiconductor device 1 has a configuration in which semiconductor packages 4 are fixed on a base plate 2 with insulation members 3 being interposed therebetween and tip portions 5a of conductive members 5 of semiconductor packages 4 and control electrodes 7b of a control substrate 7 are connected by flexible wirings 8. Although details of each semiconductor package 4 and control substrate 7 will be described later, protrusions 6a formed in semiconductor package 4 are inserted in through holes 7a of control substrate 7.

Base plate 2 is a substrate to which semiconductor package 4 is fixed, and dissipates heat generated in semiconductor package 4 to outside. For base plate 2, a plate metal containing copper as a main component may be used. Insulation member 3 electrically insulates base plate 2 and semiconductor package 4 from each other, and transfers heat generated by semiconductor package 4 to base plate 2. An insulation member obtained by mixing an epoxy resin having an insulation property with silica serving as a filler may be used as insulation member 3.

Flexible wiring 8 is a conductive wiring having flexibility, and is connected at a first connection point 8a and a second connection point 8b, first connection point 8a being a connection point between flexible wiring 8 and tip portion 5a of conductive member 5, second connection point 8b being a connection point between flexible wiring 8 and control electrode 7b of control substrate 7. Flexible wiring 8 is formed to be curved between first connection point 8a and second connection point 8b. When external force or stress is applied to semiconductor package 4 or control substrate 7, the curved portion of flexible wiring 8 can be displaced to suppress a load from being applied to each of first connection point 8a and second connection point 8b. For flexible wiring 8, a material such as aluminum, copper, silver, gold, or an alloy obtained by adding an additive to each of these can be used, and it is preferable to use a material that is less likely to cause a chemical change such as oxidation or corrosion. Here, when a material having elasticity or not having brittleness is selected for flexible wiring 8, flexible wiring 8 is elastically deformed in response to external force or stress, with the result that fatigue or damage can be less likely to be caused in flexible wiring 8. A conductive wiring or ribbon having a diameter or width of about 0.1 mm or more and 2 mm or less can be used for flexible wiring 8.

FIG. 2 is a schematic diagram showing a schematic configuration of semiconductor package 4 included in semiconductor device 1 of the present embodiment. As shown in FIG. 2, semiconductor package 4 has the plurality of protrusions 6a formed by covering the respective perimeters of tip portions 5a of the plurality of conductive members 5 with sealing resin 6.

Each of protrusions 6a may have shape and size with which it can be inserted into through hole 7a of control substrate 7. The diameter of protrusion 6a can be about 0.5 mm or more and 10 mm or less, and the height thereof can be about 0.1 mm or more and 5 mm or less. For example, when the shape of protrusion 6a is a rectangular parallelepiped shape, the width or depth thereof can be about 0.1 mm or more and 10 mm or less, and the height thereof can be about 0.1 mm or more and 5 mm or less. Sealing resin 6 covers the outer periphery of semiconductor package 4 except for the upper portion of tip portion 5a of each conductive member 5 and the bottom surface of semiconductor package 4, and the upper end of tip portion 5a connected to flexible wiring 8 is exposed. The upper surface of sealing resin 6 is provided with a supporting surface 6b, which is a flat surface, at a portion other than protrusion 6a, and supporting surface 6b can support control substrate 7. Here, the plurality of exposed portions of tip portions 5a of conductive members 5 shown in FIG. 2 are electrodes each used for feeding of a power supply voltage or a control voltage, detection of an operation current or an operation temperature, or the like.

FIG. 3 is a schematic cross sectional view of semiconductor package 4 along an A-A plane of FIG. 2. An electrode (not shown) on the lower surface side of each of two semiconductor elements 9 is connected to conductive member 5 via a lower surface bonding layer 10 and a relay electrode 11, and an electrode (not shown) on the upper surface side of each of two semiconductor elements 9 is connected to conductive member 5 via an upper surface bonding layer 12.

As shown in FIG. 3, conductive members 5 include conductive member 5 connected to relay electrode 11 and conductive member 5 connected to the electrode of semiconductor element 9 via upper surface bonding layer 12, and each of conductive members 5 extends upward in semiconductor package 4 and has tip portion 5a higher than supporting surface 6b of semiconductor package 4. The width of the exposed portion of the upper end of tip portion 5a shown in FIG. 3 may be such that flexible wiring 8 can be connected thereto, and is about 0.1 mm or more and 5 mm or less. For conductive member 5, a conductive material such as a copper alloy or an iron alloy can be used.

Scaling resin 6 has an insulation property, seals semiconductor element 9, relay electrode 11, and conductive member 5, covers the perimeter of tip portion 5a of conductive member 5, and forms protrusion 6a to be higher than supporting surface 6b. When protrusion 6a is formed, the side portion of tip portion 5a of conductive member 5 is insulated to attain a long distance between the exposed portions along the surface of sealing resin 6, with the result that discharging between the electrodes of semiconductor element 9 can be suppressed to improve the insulation properties of semiconductor package 4 and semiconductor device 1. For sealing resin 6, a material containing an epoxy resin as a main component with a silica powder being mixed as a filler can be used.

For semiconductor element 9, an element such as an IGBT (Insulated Gate Bipolar Transistor), a MOSFET (Metal-Oxide-Semiconductor Field-Effect Transistor), or an FWD (Free Wheeling Diode) is used, and one type of element or a combination of two or more types of elements may be used in one semiconductor package, and one element or a plurality of elements may be used. A semiconductor material such as silicon, silicon carbide, or gallium nitride can be used for semiconductor element 9. Semiconductor element 9 shown in FIG. 3 represents an example in which electrodes are disposed at the upper surface and the lower surface thereof, and the electrode (not shown) on the lower surface side is, for example, a drain electrode whereas the electrode (not shown) on the upper surface side is, for example, a source electrode. Further, semiconductor element 9 may include an electrode used for feeding of a power supply voltage or a control voltage, detection of an operation current or an operation temperature, or the like.

Lower surface bonding layer 10 connects the electrode on the lower surface side of semiconductor element 9 to an electrode pattern disposed at relay electrode 11 so as to electrically connect semiconductor element 9 to conductive member 5. Upper surface bonding layer 12 electrically connects the electrode on the upper surface side of semiconductor element 9 to conductive member 5. For each of lower surface bonding layer 10 and upper surface bonding layer 12, a solder, which is a low-melting point metal material, or a cured silver paste containing conductive particles may be used. For relay electrode 11, a plate-shaped or block-shaped material having electrical conductivity and thermal conductivity may be used, such as copper or aluminum. Alternatively, semiconductor element 9 may be connected to conductive member 5 via lower surface bonding layer 10, and conductive member 5 may be curved to extend upward so as to serve as relay electrode 11.

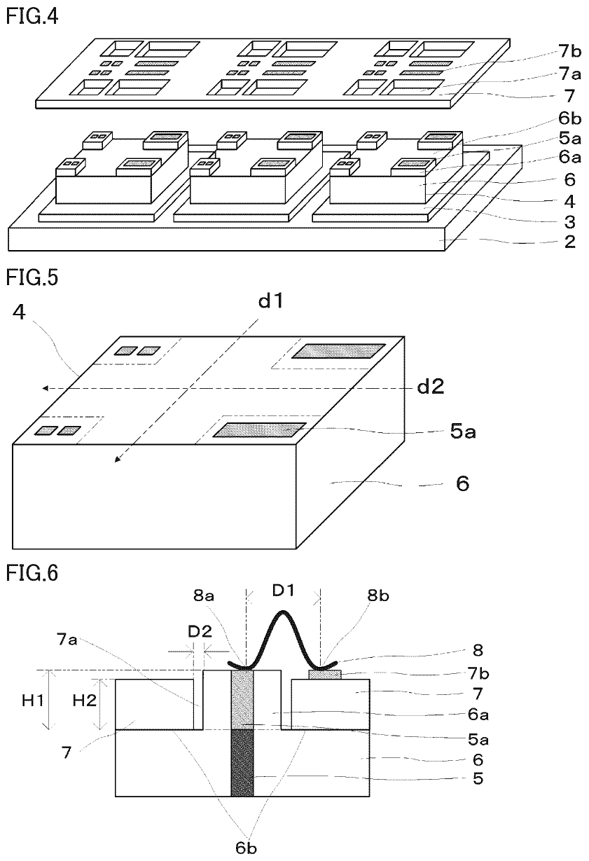

FIG. 4 is an explanatory diagram showing a correspondence relation between semiconductor packages 4 and control substrate 7 in the present embodiment. Control substrate 7 is provided with: through holes 7a into which protrusions 6a of semiconductor packages 4 are to be inserted; and control electrodes 7b to which flexible wirings 8 are to be connected.

Control substrate 7 controls a power supply voltage, a control voltage, or the like for semiconductor element 9. Control substrate 7 may include an electrode used for detection of an operation current, an operation temperature, or the like of semiconductor element 9. A printed circuit board, in which a copper wiring is formed at a glass epoxy substrate obtained by impregnating a glass fiber with an epoxy resin, may be used as control substrate 7, and the thickness thereof is about 0.1 mm or more and 3 mm or less.

Each of through holes 7a may have shape and size with which protrusion 6a can be inserted thereto. The opening diameter of through hole 7a may be about 0.5 mm or more and 10 mm or less, and the depth of the hole may be equivalent to the thickness of control substrate 7. For example, in the case where the shape of the opening thereof is a rectangular shape when viewed in a plan view, the width or depth thereof may be about 0.5 mm or more and 10 mm or less. Through hole 7a can be formed by an NC processing machine, a laser processing machine, or the like. The width and depth of through hole 7a are larger than the width and depth of protrusion 6a of semiconductor package 4 respectively and may be appropriately adjusted in accordance with the size of each of parts of a formed clearance on the left and right sides with respect to protrusion 6a when protrusion 6a is inserted in through hole 7a. When the sizes of the parts of the clearance on the left and right sides are made the same, the size of the clearance on one side is preferably 0.1 mm or more and 5 mm or less. When the clearance is made small, the wiring length of flexible wiring 8 can be shortened to reduce an amount of use of the material of flexible wiring 8, and protrusion 6a and through hole 7a are facilitated to come into contact with each other when external force or stress is applied to semiconductor device 1, with the result that flexible wiring 8 is less likely to be stretched and an excessive load can be suppressed from being applied to flexible wiring 8. When the clearance is made large, protrusion 6a is facilitated to be inserted into through hole 7a to result in improved assembly precision, thereby suppressing a trouble due to insufficient insertion or the like.

Control electrode 7b is an electrode connected to a copper wiring formed at control substrate 7 and used for feeding of a power supply voltage or a control voltage for semiconductor element 9, detection of an operation current or an operation temperature, or the like. For control electrode 7b, copper can be used, a metal material obtained through a process of plating copper with nickel, gold, or the like may be used, and it is preferable to select a material by which a desired bonding strength can be attained in the connection with flexible wiring 8. Further, a distance from control electrode 7b to the opening end portion of through hole 7a is preferably 0.5 mm or more and 10 mm or less, and when the distance is made short, the wiring length of flexible wiring 8 can be shortened to reduce the amount of use of the material of flexible wiring 8, whereas when the distance is made long, control electrode 7b can be suppressed from being deformed, lost or damaged presumably when forming the opening.

Next, a method of manufacturing semiconductor device 1 in the present embodiment will be described. The method of manufacturing semiconductor device 1 includes: a semiconductor package fixing step of fixing semiconductor package 4 to base plate 2; a protrusion inserting step of inserting protrusion 6a of semiconductor package 4 into through hole 7a of control substrate 7; and a flexible wiring connecting step of connecting, by flexible wiring 8, tip portion 5a of conductive member 5 of semiconductor package 4 to control electrode 7b of control substrate 7.

In the semiconductor package fixing step, insulation member 3 that is in the form of a liquid or sheet and that has adhesiveness and a thermosetting property is applied or adhered to base plate 2, semiconductor package 4 is placed at a desired position thereon and heating is performed to cure insulation member 3, thereby fixing semiconductor package 4 to base plate 2 as shown in FIG. 1.

In the protrusion inserting step, as shown in FIG. 4, the position of through hole 7a of control substrate 7 is adjusted to correspond to the position of protrusion 6a of semiconductor package 4, and protrusion 6a is inserted into through hole 7a. Control substrate 7 may be fixed to semiconductor package 4 by applying a resin material having adhesiveness and a thermosetting property such as an epoxy resin, a polyurethane resin, or a silicone resin on the flat upper surface of semiconductor package 4 other than protrusion 6a, adhering them together, and performing heating to cure the resin material. Here, apart from the adhesion by the resin material, a mechanical fixing method such as fixing using a mechanism such as a screw or a hook may be used as the fixing method.

In the flexible wiring connecting step, tip portion 5a of conductive member 5 and control electrode 7b of control substrate 7 are connected to each other by flexible wiring 8 through ultrasonic bonding by a wire bonder. When a ribbon-shaped wire is used for flexible wiring 8, a dedicated processing tool may be used for the wire bonder. Here, apart from the wire bonding by the wire bonder, a method of soldering a metal wiring that is insulation-coated at portions other than its tip for the sake of connection can be used as the connection method.

Here, a method of manufacturing semiconductor package 4 will be described. Semiconductor package 4 includes: a semiconductor element bonding step of bonding semiconductor element 9 to relay electrode 11; a conductive member bonding step of bonding conductive members 5 to semiconductor element 9 and relay electrode 11; and a sealing step of covering conductive members 5, the perimeter of tip portion 5a of each conductive member 5, and semiconductor element 9 with sealing resin 6.

In the semiconductor element bonding step, the lower surface electrode of semiconductor element 9 is bonded to relay electrode 11 by soldering or by applying and sintering a conductive paste, thereby fixing semiconductor element 9 to relay electrode 11 as shown in FIG. 2. The bonding portion of relay electrode 11 may be subjected to nickel plating or surface treatment such as plasma irradiation so as to improve a bonding property between semiconductor element 9 and relay electrode 11.

In the conductive member bonding step, conductive members 5 are bonded to semiconductor element 9 and relay electrode 11 by soldering, thereby fixing curved conductive members 5 to extend upward in semiconductor package 4 as shown in FIG. 3.

In the sealing step, conductive members 5 and semiconductor element 9 are sealed by so-called transfer molding as follows: semiconductor element 9 and relay electrode 11 to which conductive members 5 are bonded are placed in a mold, a molten sealing resin material is poured into the mold, and the entire mold is heated to cure the sealing resin material, thereby forming sealing resin 6 in one piece. Here, by providing a rectangular-parallelepiped-shaped space in a portion of the mold corresponding to protrusion 6a of sealing resin 6, protrusion 6a having a rectangular parallelepiped shape can be formed by the transfer molding. Here, when the resin sealing is performed by the transfer molding without forming this space, protrusion 6a is not formed as shown in FIG. 5; however, protrusion 6a can be formed by cutting, by an end mill along a cutting direction d1 and a cutting direction d2 orthogonal thereto as shown in FIG. 5, a portion other than a portion at which protrusion 6a is to be formed. In this way, the position of protrusion 6a can be changed without producing another mold for the transfer molding, thereby reducing design and manufacturing cost. Apart from the transfer molding, protrusion 6a can be also formed by performing resin coating through compression molding, potting, or the like, curing the resin, and then performing cutting, polishing, or the like.

Through the above steps, semiconductor device 1 according to the present embodiment and semiconductor package 4 to be used for semiconductor device 1 can be manufactured.

Thus, semiconductor device 1 includes: semiconductor element 9; the plurality of conductive members 5 each electrically connected to semiconductor element 9 and each extending upward; sealing resin 6 to seal semiconductor element 9 and conductive members 5 and to form protrusion 6a that covers the perimeter of tip portion 5a of each of the plurality of conductive members 5; control substrate 7 provided with through hole 7a into which protrusion 6a is inserted, control substrate 7 having control electrode 7b; and flexible wiring 8 to connect control electrode 7b and tip portion 5a of conductive member 5 to each other, flexible wiring 8 having flexibility. With such a configuration, the perimeter of tip portion 5a of conductive member 5 of semiconductor package 4 is insulated by sealing resin 6 having protrusion 6a formed therein, and it is not necessary to provide an insulation resin such as an underfill material between semiconductor package 4 and control substrate 7, with the result that a trouble such as detachment or cracking of the insulation resin does not occur even when external force or stress is applied to semiconductor device 1. Thus, a trouble due to external force or stress applied to semiconductor device 1 can be prevented, thereby obtaining semiconductor device 1 having an excellent durability. Further, semiconductor package 4 having protrusion 6a formed therein can be used to manufacture such a semiconductor device 1.

It should be noted that in the present embodiment, exemplary sealing resin 6 has been illustrated in which protrusion 6a is formed to entirely cover the perimeter of tip portion 5a of each of the plurality of conductive members 5; however, sealing resin 6 may be configured in the following manner: protrusion 6a is formed such that a portion of the perimeter of tip portion 5a at or below the height of the upper surface of control substrate 7 is covered with sealing resin 6, i.e., protrusion 6a is formed such that a portion of the perimeter of tip portion 5a above the height of the upper surface of control substrate 7 is not covered with sealing resin 6. Further, it has been illustratively described that the upper end of tip portion 5a of each conductive member 5 is entirely exposed as shown in FIG. 3; however, a portion of the upper end of tip portion 5a may be covered with sealing resin 6 as long as the exposed portion of the upper end of tip portion 5a is exposed to such an extent that flexible wiring 8 can be connected thereto. For example, the width of the exposed portion of the upper end of tip portion 5a can be about the half of the width of tip portion 5a. The insulation property of semiconductor device 1 is secured also by these configurations of tip portion 5a with regard to the exposure in the upward/downward direction and leftward/rightward direction, with the result that sealing precision of sealing resin 6 is mitigated or connection of flexible wiring 8 is facilitated in the manufacturing of semiconductor package 4.

Further, as shown in FIG. 6, a protrusion height H1 is a length from the lower end of protrusion 6a to the upper end of protrusion 6a, i.e., is a length from the surface of semiconductor package 4 at which protrusion 6a is formed to the upper end of protrusion 6a, and is preferably more than or equal to thickness H2 of control substrate 7, and the upper end of protrusion 6a is preferably located above the upper surface of control substrate 7. In FIG. 6, the upper end of protrusion 6a is located above the upper surface of control substrate 7 by a difference between height H1 of protrusion 6a and thickness H2 of control substrate 7. With this configuration, insertion of protrusion 6a into through hole 7a is facilitated, thereby suppressing a trouble in fixing semiconductor package 4 and control substrate 7, a trouble in connecting flexible wiring 8, or the like due to insufficient insertion. Further, supporting surface 6b of semiconductor package 4 and the lower surface of control substrate 7 may be in contact with each other or may be separated from each other.

Further, as shown in FIG. 6, in a relation among an inter-connection-point distance D1 that is a length between first connection point 8a and second connection point 8b, the length of flexible wiring 8 from first connection point 8a to second connection point 8b, and a permissible width D2 that is a width between the side portion of protrusion 6a and the opening end of through hole 7a of control substrate 7, the length of flexible wiring 8 is preferably longer than the total of inter-connection-point distance D1 and permissible width D2, first connection point 8a being a connection point between flexible wiring 8 and tip portion 5a, second connection point 8b being a connection point between flexible wiring 8 and control electrode 7b. With this configuration, even when protrusion 6a and control substrate 7 are moved in the lateral direction due to generated external force or stress to cause the side portion of protrusion 6a to collide with the opening end of through hole 7a, the curved portion of flexible wiring 8 is not stretched to the maximum, with the result that a load can be suppressed from being applied to each of first connection point 8a and second connection point 8b of flexible wiring 8.

Further, the shape of protrusion 6a may be a polygonal prism shape, a cylindrical shape, or the like instead of the rectangular parallelepiped shape shown in FIG. 2, and the shape of through hole 7a of control substrate 7 may be selected in accordance with the shape of protrusion 6a. Further, it has been illustratively described that supporting surface 6b of semiconductor package 4 is flat; however, supporting surface 6b may not be completely flat, may have irregularities, or may have a spherical surface such as a shape of dome.

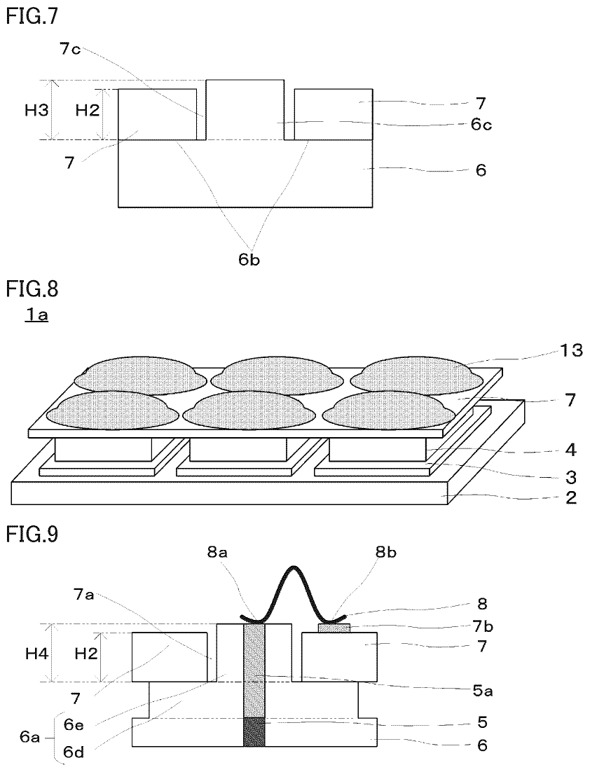

Further, as shown in FIG. 7, semiconductor package 4 may include a second protrusion 6c that is provided at supporting surface 6b, that is composed of sealing resin 6, and that does not include tip portion 5a of conductive member 5. By providing a second through hole 7c in control substrate 7 so as to correspond to second protrusion 6c and inserting second protrusion 6c into second through hole 7c, semiconductor package 4 and control substrate 7 are fixed to each other more stably. Therefore, even when external force or stress is applied to semiconductor device 1 or semiconductor package 4 to urge movement of protrusion 6a and control substrate 7 in the lateral direction, protrusion 6a and control substrate 7 are regulated, with the result that the curved portion of flexible wiring 8 is not stretched to the maximum to thereby further suppress a load from being applied to each of first connection point 8a and second connection point 8b of flexible wiring 8. The shape of second protrusion 6c may be a rectangular parallelepiped shape, a polygonal prism shape, a cylindrical shape, or the like. Further, the diameter of second protrusion 6c can be about 0.5 mm or more and 10 mm or less, and the height thereof can be about 0.1 mm or more and 5 mm or less. For example, when the shape of second protrusion 6c is a rectangular parallelepiped shape, the width or depth thereof can be about 0.5 mm or more and 10 mm or less and the height thereof can be about 0.1 mm or more and 5 mm or less.

Further, second through hole 7c may have shape and size with which second protrusion 6c can be inserted thereto, and the opening diameter of second through hole 7c may be about 0.5 mm or more and 10 mm or less, and the depth of the hole may be equivalent to the thickness of control substrate 7. For example, in the case where the opening shape of second through hole 7c is a rectangular shape when viewed in a plan view, the width or depth of the opening diameter can be about 0.5 mm or more and 10 mm or less. Second through hole 7c can be formed by an NC processing machine, a laser processing machine, or the like. The width and depth of second through hole 7c are larger than the width and depth of second protrusion 6c respectively, and may be appropriately adjusted in accordance with the size of each of parts of a formed clearance on the left and right sides with respect to second protrusion 6c when second protrusion 6c is inserted in second through hole 7c. When the sizes of the parts of the clearance on the left and right sides are made the same, the size of the clearance on one side is preferably 0.1 mm or more and 5 mm or less. When the clearance is made small, second protrusion 6c and second through hole 7c are facilitated to come into contact with each other when external force or stress is applied to semiconductor device 1, with the result that flexible wiring 8 is less likely to be stretched and an excessive load can be suppressed from being applied to flexible wiring 8. When the clearance is made large, second protrusion 6c is facilitated to be inserted into second through hole 7c to result in improved assembly precision, thereby suppressing a trouble due to insufficient insertion or the like.

Further, as shown in FIG. 7, a second protrusion height H3 is a length from the lower end of second protrusion 6c to the upper end of second protrusion 6c, i.e., is a length from the surface of semiconductor package 4 at which second protrusion 6c is formed to the upper end of second protrusion 6c, and is preferably more than or equal to thickness H2 of control substrate 7, and the upper end of protrusion 6a is preferably located above the upper surface of control substrate 7. In FIG. 7, the upper end of protrusion 6a is located above the upper surface of control substrate 7 by a difference between second protrusion height H3 and thickness H2 of control substrate 7. With this configuration, insertion of protrusion 6a into through hole 7a is facilitated, thereby suppressing a trouble in fixing semiconductor package 4 and control substrate 7, a trouble in connecting flexible wiring 8, or the like due to insufficient insertion.

Further, in the case where the sizes of the parts of the formed clearance on the left and right sides with respect to second protrusion 6c when second protrusion 6c is inserted into through hole 7a are made the same, the clearance on one side is preferably 0.5 mm or more and 5 mm or less. With the small clearance on one side, even when external force or stress is applied to semiconductor device 1 or semiconductor package 4 to urge movement of protrusion 6a and control substrate 7 in the lateral direction, second protrusion 6c and through hole 7a come into contact with each other to avoid protrusion 6a and control substrate 7 from being moved in the lateral direction and avoid the curved portion of flexible wiring 8 from being stretched to the maximum, thereby further suppressing a load from being applied to each of first connection point 8a and second connection point 8b of flexible wiring 8. When the clearance is made large, protrusion 6a is facilitated to be inserted into through hole 7a to result in improved assembly precision, thereby suppressing a trouble due to insufficient insertion or the like.

Further, the following semiconductor device 1a may be employed as shown in FIG. 8: a bonding protection member 13 to cover tip portion 5a of conductive member 5, control electrode 7b of control substrate 7, and flexible wiring 8 is formed on control substrate 7 of semiconductor device 1 shown in FIG. 1. Bonding protection member 13 has elasticity and protects tip portion 5a, control electrode 7b, or flexible wiring 8 from external force or stress applied to semiconductor device 1a. When a relatively flexible resin having an elastic modulus of 1 MPa or more and less than 1000 MPa is used as bonding protection member 13, bonding protection member 13 can be facilitated to follow displacement and deformation of flexible wiring 8 caused by external force or stress applied to semiconductor device 1a, thereby suppressing a load from being applied to each of first connection point 8a and second connection point 8b of flexible wiring 8. On the other hand, when a resin that has an elastic modulus of 1 GPa or more and 10 GPa or less and that is relatively less likely to be elastically deformed is used, the fixation between semiconductor package 4 and control substrate 7 can be enhanced and flexible wiring 8 can be fixed to suppress displacement and deformation of flexible wiring 8 due to external force applied to semiconductor device 1a, thereby suppressing a load from being applied to each of first connection point 8a and second connection point 8b of flexible wiring 8. Further, bonding protection member 13 has an insulation property, and the insulation property among tip portion 5a, control electrode 7b, and flexible wiring 8 is improved by covering them. For bonding protection member 13, a thermosetting resin, an ultraviolet curable resin, or the like can be used, such as silicone, fluorine, polyurethane, polyolefin, or polyimide. Further, the elastic modulus of bonding protection member 13 may be adjusted by dispersing a filler in bonding protection member 13. Here, in order to form bonding protection member 13 at a desired position of control substrate 7 to have a desired shape, bonding protection member 13 preferably has thixotropy before being cured.

Further, in the bonding protection forming step of forming bonding protection member 13, a source material of the bonding protection member is applied using a dispenser, a slit coater, or the like so as to cover tip portion 5a of conductive member 5, control electrode 7b of control substrate 7, and flexible wiring 8 or so as to cover the entire upper surface of control substrate 7, and is then cured. When the thermosetting resin is selected as the material of bonding protection member 13, the thermosetting resin is cured by heating, whereas when the ultraviolet curable resin is selected, the ultraviolet curable resin is cured by irradiating the ultraviolet curable resin with an ultraviolet ray having a wavelength suitable for the resin.

It has been illustratively described that the plurality of semiconductor packages 4, the plurality of semiconductor elements 9, and the plurality of conductive members 5 are provided; however, the numbers of semiconductor packages 4, semiconductor elements 9, and conductive members 5 may be changed as appropriate. For example, four semiconductor elements 9 may be provided, and eight conductive members 5 may be provided. Here, each of semiconductor packages 4 may include a plurality of electrodes each used for feeding of a power supply voltage or a control voltage to semiconductor element 9, detection of an operation current or operation temperature of semiconductor element 9, or the like and the number of conductive members 5 may be increased accordingly.

It has been illustratively described that the electrodes (not shown) of semiconductor element 9 are disposed at the upper surface and lower surface of semiconductor element 9; however, the plurality of electrodes may be disposed only at the upper surface of semiconductor element 9. In this case, the plurality of conductive members 5 are connected to the plurality of electrodes at the upper surface of semiconductor element 9 via upper surface bonding layer 12.

Also with such a configuration, the perimeter of tip portion 5a of conductive member 5 of semiconductor package 4 is insulated and it is not necessary to provide an insulation resin such as an underfill material between semiconductor package 4 and control substrate 7, with the result that a trouble such as detachment, cracking, or the like of the insulation resin do not occur even when external force or stress is applied to semiconductor device 1. Further, even when external force or stress is applied to semiconductor device 1, bonding protection member 13 follows flexible wiring 8 or bonding protection member 13 fixes flexible wiring 8, thereby suppressing a load from being applied to each of first connection point 8a and second connection point 8b of flexible wiring 8. Therefore, a trouble due to external force or stress applied to semiconductor device 1 can be prevented, and semiconductor device 1 or semiconductor package 4 having an excellent durability can be obtained.

### Second Embodiment

In the first embodiment, it has been illustratively described that the shape of protrusion 6a of semiconductor package 4 is a rectangular parallelepiped shape; however, in the present embodiment, it will be illustratively described that protrusion 6a has a stepped shape. Configurations other than this are the same as those in the first embodiment.

FIG. 9 is a schematic cross sectional view showing a relation between protrusion 6a of semiconductor package 4 and control substrate 7 in the present embodiment. Protrusion 6a has a stepped shape including: a lower stage having a supporting portion 6d; and an upper stage having an insertion portion 6e and located above the lower stage. Supporting portion 6d supports the lower surface of control substrate 7, and insertion portion 6e is inserted into through hole 7a of control substrate 7. Here, the upper surface of supporting portion 6d supports control substrate 7.

The diameter of supporting portion 6d is larger than the opening diameter of through hole 7a of control substrate 7, and the diameter of insertion portion 6e is smaller than the opening diameter of through hole 7a of control substrate 7. The diameter of insertion portion 6e can be about 0.5 mm or more and 10 mm or less, and the height thereof can be about 0.1 mm or more and 5 mm or less. For example, when the insertion portion is in the form of a rectangular parallelepiped, the width or depth thereof can be about 0.5 mm or more and 10 mm or less, and the height thereof can be about 0.1 mm or more and 5 mm or less. The diameter of supporting portion 6d may be larger than the diameter of insertion portion 6e and may be such that the lower surface of control substrate 7 can be supported.

At the upper end portion of insertion portion 6e, tip portion 5a of conductive member 5 is exposed and this exposed portion serves as a point of connection with flexible wiring 8. Further, an insertion portion height H4 is a length from the upper end of supporting portion 6d to the upper end of insertion portion 6e, and is preferably more than or equal to thickness H2 of control substrate 7, and the upper end of insertion portion 6e is preferably located above the upper surface of control substrate 7. In FIG. 9, the upper end of insertion portion 6e is located above the upper surface of control substrate 7 by a difference between insertion portion height H4 and thickness H2 of control substrate 7. With this configuration, when circuit wiring and component are mounted on the rear surface of control substrate 7, or when an irregularity portion exists at a portion of semiconductor package 4 other than protrusion 6a, semiconductor package 4 and control substrate 7 do not come into contact with each other and are disposed in parallel with each other, with the result that insertion of protrusion 6a is less likely to be insufficient. Further, since the insertion is avoided from being insufficient, flexible wiring 8 can be readily connected.

Here, control substrate 7 is formed by heating an epoxy resin formed to have a plate shape, and may be warped by heating, moisture absorption, or the like. With the above-described configuration, even when the entire surface of control substrate 7 is thus warped, semiconductor package 4 and control substrate 7 do not come into contact with each other and are disposed in parallel with each other, with the result that insertion of protrusion 6a is less likely to be insufficient. Further, since the insertion is avoided from being insufficient, flexible wiring 8 can be readily connected.

Also with such a configuration, the perimeter of tip portion 5a of each of the plurality of conductive members 5 of semiconductor package 4 is insulated by sealing resin 6 having protrusion 6a formed therein, and it is not necessary to provide an insulation resin such as an underfill material between semiconductor package 4 and control substrate 7, with the result that a trouble such as detachment, cracking or the like of the insulation resin do not occur even when external force or stress is applied to semiconductor device 1. Therefore, a trouble due to external force or stress applied to semiconductor device 1 can be prevented, and semiconductor device 1 or semiconductor package 4 having an excellent durability can be obtained.

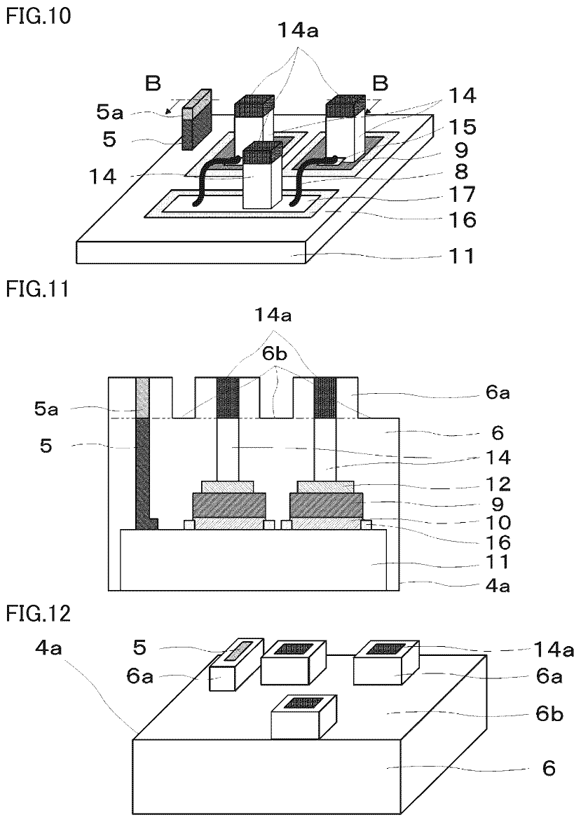

In each of the first and second embodiments, it has been illustratively described that the conductive material curved to extend upward in semiconductor package 4 is used for conductive member 5; however, an electrode post 14 may be used for conductive member 5, flexible wiring 8 may be used for the wiring connected to the electrode of semiconductor element 9, and a semiconductor package 4a may be configured as shown in FIGS. 10 to 12. Here, FIG. 10 is a schematic diagram showing a schematic configuration of semiconductor package 4a, FIG. 11 is a schematic cross sectional view of semiconductor package 4a along a B-B plane of FIG. 10, and FIG. 12 is a schematic diagram showing the schematic configuration of semiconductor package 4a. For clarity of explanation, sealing resin 6 is not shown in FIG. 10.

As shown in FIG. 10, electrode post 14 having a columnar shape and electrical conductivity is used as conductive member 5, and electrode post 14 is electrically connected to semiconductor element 9 and extends upward in semiconductor package 4a. Electrode post 14 is also connected to a conductive layer 17, which is a conductive pattern provided on an insulation layer 16 having an insulation property. Semiconductor element 9 is fixed to relay electrode 11 with insulation layer 16 being interposed therebetween. A control terminal 15, which is an electrode different from the electrode to which electrode post 14 is connected, is provided at semiconductor element 9, and control terminal 15 is, for example, a gate electrode terminal when semiconductor element 9 is a MOSFET. Control terminal 15 and conductive layer 17 are connected to each other by flexible wiring 8. For example, for formation and connection of flexible wiring 8, wire bonding can be used.

As shown in FIG. 11, electrode post 14 is sealed with sealing resin 6, and protrusion 6a that covers the perimeter of an electrode post tip portion 14a is formed by sealing resin 6. The upper end of electrode post tip portion 14a is not covered with sealing resin 6 and is exposed to outside, and flexible wiring 8 is connected to the exposed portion. A metal material such as copper or nickel may be used for electrode post 14, and the perimeter of electrode post 14 other than the upper and lower ends thereof, i.e., the side surfaces of electrode post 14 may be covered with an insulation material such as an epoxy resin, a polyimide resin, or a silicone resin by using an electrodeposition coating, for example. Then, for example, sealing resin 6 can be formed by the transfer molding to obtain semiconductor package 4a having protrusion 6a as shown in FIG. 12.

In this way, in the case where semiconductor package 4a is manufactured using flexible wiring 8 together with electrode post 14, conductive member 5 does not need to be redesigned or manufactured even when the layout of semiconductor element 9 is changed, thereby reducing design cost.

Also with such a configuration, the perimeter of electrode post tip portion 14a of electrode post 14 used as conductive member 5 of semiconductor package 4a is insulated by sealing resin 6 having protrusion 6a formed therein, and it is not necessary to provide an insulation resin such as an underfill material between semiconductor package 4a and control substrate 7, with the result that a trouble such as detachment, cracking, or the like of the insulation resin do not occur even when external force or stress is applied to semiconductor device 1. Therefore, a trouble due to external force or stress applied to semiconductor device 1 can be prevented, and semiconductor device 1 or semiconductor package 4a having an excellent durability can be obtained.

In addition to the above, the embodiments can be freely combined, any component of the embodiments can be modified, or any component of the embodiments can be omitted.

### REFERENCE SIGNS LIST

1, 1a: semiconductor device; 2: base plate; 3: insulation member; 4, 4a: semiconductor package; 5: conductive member; 5a: tip portion; 6: sealing resin; 6a: protrusion; 6b: supporting surface; 6c: second protrusion; 6d: supporting portion; 6e: insertion portion; 7: control substrate; 7a: through hole; 7b: control electrode; 7c: second through hole; 8: flexible wiring; 8a: first connection point; 8b: second connection point; 9: semiconductor element; 10: lower surface bonding layer, 11: relay electrode; 12: upper surface bonding layer; 13: bonding protection member; 14: electrode post; 14a: electrode post tip portion; 15: control terminal; 16: insulation layer, 17: conductive layer; d1, d2: cutting direction; D1: inter-connection-point distance; D2: permissible width; H1: protrusion height; H2: control substrate thickness; H3: second protrusion height; H4: insertion portion height.

1. A semiconductor device comprising:
a semiconductor element;
a plurality of conductive members each electrically connected to the semiconductor element and each extending upward;
a sealing resin to seal the semiconductor element and the conductive members and to form a protrusion that covers a perimeter of a tip portion of each of the plurality of conductive members;
a control substrate provided with a through hole into which the protrusion is inserted, the control substrate having a control electrode; and
a flexible wiring to connect the control electrode and the tip portion of the conductive member to each other, the flexible wiring having flexibility.

2. The semiconductor device according to claim 1, wherein a height of the protrusion is a length from a lower end of the protrusion to an upper end of the protrusion and is more than or equal to a thickness of the control substrate, and the upper end of the protrusion is located above an upper surface of the control substrate.

3. The semiconductor device according to claim 1, wherein the protrusion includes a lower stage having a supporting portion to support a lower surface of the control substrate and an upper stage having an insertion portion inserted into the through hole, a height of the insertion portion is more than or equal to a thickness of the control substrate, and an upper end of the insertion portion is located above an upper surface of the control substrate.

4. The semiconductor device according to claim 1, wherein an upper surface of the sealing resin other than the protrusion is flat.

5. The semiconductor device according to claim 1, wherein in a relation among an inter-connection-point distance that is a length between a first connection point and a second connection point, a length of the flexible wiring from the first connection point to the second connection point, and an permissible width that is a width between a side portion of the protrusion and an opening end of the through hole, the length of the flexible wiring is longer than a total of the inter-connection-point distance and the permissible width, the first connection point being a connection point between the flexible wiring and the tip portion, the second connection point being a connection point between the flexible wiring and the control electrode.

6. The semiconductor device according to claim 1, wherein a bonding protection member to cover the tip portion, the control electrode, and the flexible wiring and to electrically insulate the tip portion, the control electrode, and the flexible wiring from one another is further formed on the control substrate.

7. The semiconductor device according to claim 1, wherein the semiconductor device has a structure in which a second protrusion that is composed of the sealing resin and that does not include the conductive member is provided at an upper surface of the sealing resin other than the protrusion and the second protrusion is inserted into a second through hole of the control substrate, the second through hole being provided to correspond to the second protrusion.

8. A method of manufacturing a semiconductor device, the method comprising:
a semiconductor package fixing step of fixing a semiconductor package to a base plate, the semiconductor package having a sealing resin to form a protrusion that covers a perimeter of a tip portion of each of a plurality of conductive members;
a protrusion inserting step of inserting the protrusion into a through hole provided in a control substrate; and
a flexible wiring connecting step of connecting, by a flexible wiring through wire bonding, the tip portion to a control electrode provided on the control substrate.

9. The method of manufacturing the semiconductor device according to claim 8, further comprising a bonding protection member forming step of forming, on the control substrate, a bonding protection member to cover the tip portion, the control electrode, and the flexible wiring and to electrically insulate the tip portion, the control electrode, and the flexible wiring from one another.

10. A semiconductor package comprising:
a semiconductor element;
a plurality of conductive members each electrically connected to the semiconductor element and each extending upward; and
a sealing resin to seal the semiconductor element and the conductive members and to form a protrusion that covers a perimeter of a tip portion of each of the plurality of conductive members.

11. The semiconductor package according to claim 10, wherein the protrusion is constituted of a lower stage having a supporting portion and an upper stage having an insertion portion and located above the lower stage, and a diameter of the lower stage is larger than a diameter of the upper stage.

12. The semiconductor package according to claim 10, wherein an upper surface of the sealing resin other than the protrusion is flat.

13. The semiconductor package according to claim 10, wherein a second protrusion that is composed of the sealing resin and that does not include the conductive member is further provided at an upper surface of the sealing resin other than the protrusion.
